(19) United States
(12) Patent Application Publication
(10) Pub. No.: US 2012/0293739 A1
(43) Pub. Date: Nov. 22, 2012

(54) ARRAY SUBSTRATE FOR LIQUID CRYSTAL PANEL AND LIQUID CRYSTAL DISPLAY DEVICE EQUIPPED WITH SAID SUBSTRATE

(75) Inventor: Ryoh Ohue, Osaka (JP)

(73) Assignee: SHARP KABUSHIKI KAISHA, Osaka (JP)

(21) Appl. No.: 13/519,710

(22) PCT Filed: Dec. 3, 2010
(86) PCT No.: PCT/JP2010/071630

§ 371 Date: Jul. 10, 2012

(30) Foreign Application Priority Data
Dec. 29, 2009 (JP) 2009-299194

(51) Int. Cl. G02F 1/136; H01L 27/105

(52) U.S. Cl. 349/43; 257/59; 257/E27.081

(57) ABSTRACT

Provided is an array substrate for liquid crystal panel that is capable of suppressing an occurrence of short circuits between a pair of substrates having liquid crystal sealed therebetween. In this array substrate for liquid crystal panel 12, a thin film transistor 30 is formed so as to have a multilayer structure that includes at least a gate electrode 32, a source electrode 36, and a drain electrode 37. In at least a portion of a thin film transistor formation portion, a substrate main body (glass substrate) 12of the array substrate 12 has a recessed portion 33 that is recessed from an area surrounding the thin film transistor formation portion. One of the gate electrode, the source electrode, and the drain electrode is formed such that at least a portion thereof is embedded in the recessed portion.

### TECHNICAL FIELD

The present invention relates to a liquid crystal display device and to an array substrate for liquid crystal panel that is used to constitute a liquid crystal panel equipped in the display device.

The present application claims priority to Patent Application No. 2009-299194 filed in Japan on Dec. 29, 2009, and the entire contents of which are hereby incorporated by reference.

Liquid crystal display devices having liquid crystal panels are widely used as image display devices (displays) for televisions, personal computers, and the like.

The liquid crystal panel has a pair of substrates (i.e., an array substrate and an opposite substrate that is disposed so as to face the array substrate) and a liquid crystal layer disposed between the pair of substrates. An image is displayed by selectively applying a voltage on the array substrate and the opposite substrate in the respective pixels so as to control liquid crystal molecules in the liquid crystal layer. In an active matrix type liquid crystal panel, for example, a plurality of gate lines (scan wiring lines) and a plurality of source lines (signal wiring lines) are formed on the array substrate so as to be orthogonal to each other, and pixels having thin film transistors (TFTs) as switching elements are formed at the respective intersections of the gate lines and the source lines. Patent Document 1 is an example of a technical document related to a prior art of this type. Patent Document 1 describes a technique of planarizing a TFT formation region by forming a recessed portion in an interlayer insulating film.

### RELATED ART DOCUMENTS

### Patent Documents

Patent Document 1: Japanese Patent Application Laid-Open Publication No. H11-218781

### SUMMARY OF THE INVENTION

### Problems to be Solved by the Invention

During a step of assembling the liquid crystal panel, a foreign substance may enter the liquid crystal layer between the array substrate and the opposite substrate (color filter substrate). Because the space between the array substrate and the color filter substrate, which is disposed to face the array substrate, becomes smaller (distance becomes shorter) in intersection areas of the gate lines and the source lines formed on the array substrate, areas of the array substrate where the TFTs are formed, and the like, when the foreign substance is present in those areas, a short circuit (leakage) occurs at a higher rate. When such a defect occurs, a proper voltage is not applied on the substrates, and therefore, image display anomalies (point defect, line defect) become visible in the liquid crystal display device, which lowers the manufacturing yield. Particularly, the areas where the TFTs are formed have a multilayer structure that is constituted of a plurality of materials, and therefore, the distance to the color filter substrate tends to become smaller as compared with areas where the TFTs are not formed. If the space between the substrates is increased (if the thickness of a spacer member is increased, for example), the liquid crystal panel becomes thicker, which not only makes it impossible to meet a demand for a thin liquid crystal panel, but also may result in a longer response time and a lower contrast ratio. Further, if the wiring lines are made thinner so as to secure a sufficient space, the wiring line resistance would increase, and therefore, a signal delay would be more likely to occur. The technique described in Patent Document 1 does not solve these problems.

The present invention was made to address the problems described above, and an object of the present invention is to provide an array substrate for liquid crystal panel having a configuration that is capable of suppressing the occurrence of short circuits caused by presence of foreign substances between substrates without increasing the wiring line resistance. Another object is to provide a liquid crystal panel that has the above-mentioned array substrate for liquid crystal panel and a liquid crystal display device that has the liquid crystal panel.

### Means for Solving the Problems

In order to achieve the objects described above, the present invention provides an array substrate for liquid crystal panel that has a substrate main body, a plurality of gate lines, a plurality of source lines that intersect with the gate lines, and a plurality of thin film transistors that are electrically connected to respective gate line and respective source line. In the array substrate for liquid crystal panel disclosed here, each of the thin film transistors is formed to have a multilayer structure that has at least a gate electrode, a source electrode, and a drain electrode. Further, at least in a portion of a formation portion of each of the thin film transistors, the substrate main body has a recessed portion that is recessed from a surrounding portion of the formation portion of the thin film transistor. Here, one of the gate electrode, the source electrode, and the drain electrode is formed such that at least a portion thereof is embedded in the recessed portion.

In the array substrate for liquid crystal panel provided by the present invention, the recessed portion is formed in the thin film transistor (TFT) formation portion of the substrate main body (typically, a glass substrate). Because of this, when forming the thin film transistors, one electrode (typically, the gate electrode) of the gate electrode, the source electrode, and the drain electrode can be formed such that a portion of the electrode is embedded in the recessed portion. This way, the thickness of the TFT formation area is reduced by the amount of the thickness of the electrode (typically, the gate electrode) embedded in the recessed portion. As a result, the space between the TFT formation area of the array substrate (typically, the areas where the source electrode and the drain electrode are formed) and the color filter substrate becomes larger. Thus, it is possible to suppress the occurrence of short circuits between the substrates caused by presence of a foreign substance in the area. Furthermore, in the array substrate for liquid crystal panel according to the present invention, the substrate main body has the recessed portion as described above, and the thickness of the electrodes (wiring lines) is not reduced. Because of this, it is possible to increase the space between the above-mentioned substrates in the TFT formation area without increasing the wiring line resistance.

Thus, according to the array substrate for liquid crystal panel, it is possible to suppress the occurrence of short circuits between the substrates even when a foreign substance is present between the substrates without increasing the wiring line resistance.

In a preferred aspect of the array substrate for liquid crystal panel disclosed here, the thin film transistor has a multilayer structure that includes a gate electrode formed on the substrate main body, an insulating film that is formed close to a top of a substrate than the gate electrode, a semiconductor film that is formed closer to the top of the substrate than the insulating film, and a source electrode and a drain electrode that are formed closer to the top of the substrate than the semiconductor film. Here, at least a portion of the gate electrode is formed so as to be embedded in the recessed portion.

In the array substrate for liquid crystal panel having this configuration, when forming the TFTs, the gate electrode is formed such that a portion thereof is embedded in the recessed portion without reducing the cross-sectional area of the gate electrode (without reducing the width of the gate electrode and/or the thickness of the gate electrode). This way, the thickness of the TFT formation area is reduced by the amount of the thickness of the gate electrode embedded in the recessed portion, and the space between the TFT formation area (areas where the source electrode and the drain electrode are formed) on the array substrate and the color filter substrate is increased. Because of this, it is possible to suppress the occurrence of short circuits between the substrates caused by presence of a foreign substance in the above-mentioned area.

In another preferred aspect of the array substrate for liquid crystal panel disclosed here, in the substrate main body, at least intersection areas of the gate lines and the source lines that are disposed on the substrate main body are formed as recessed portions that are recessed from non-intersection areas adjacent to the intersection areas. Further, at least a portion of the gate lines is formed so as to be embedded in the recessed portions, and the gate lines and the source lines are arranged so as to intersect with each other over the recessed portions.

In the array substrate for liquid crystal panel having this configuration, the intersection areas of the gate lines and the source lines on the substrate main body are formed so as to be recessed; at least a portion of the gate lines is formed so as to be embedded in the recessed portions; and the gate lines and the source lines are formed so as to intersect with each other over the recessed portions. Because of this, the space between the intersection areas and the color filter substrate is increased by the thickness (height) of the portion of the gate lines embedded in the recessed portions. As a result, it is possible to suppress the occurrence of short circuits between the substrates caused by presence of a foreign substance in the above-mentioned areas.

In another preferred aspect of the array substrate for liquid crystal panel disclosed here, the recessed portions are formed continuously under the gate lines that are disposed on the substrate main body along the gate lines.

In the array substrate for liquid crystal panel having this configuration, the recessed portions are continuously formed in the substrate main body under the gate lines (including gate electrodes) that are disposed on the substrate main body. Therefore, formation of planarized gate wiring lines can be achieved. This way, in the intersection areas of the gate lines and the source lines and in the TFT formation area, the space between the array substrate and the color filter substrate can be increased. Therefore, it is possible to suppress the occurrence of short circuits between the substrates.

In another preferred aspect of the array substrate for liquid crystal panel disclosed here, the array substrate is further provided with a plurality of auxiliary capacitance lines that intersect with the source lines. In the substrate main body, at least intersection areas of the auxiliary capacitance lines and the source lines that are disposed on the substrate main body are formed as recessed portions that are recessed from non-intersection areas adjacent to the intersection areas. At least a portion of the auxiliary capacitance lines is formed so as to be embedded in the recessed portions, and the auxiliary capacitance lines and the source lines are disposed so as to intersect with each other over the recessed portions.

In the array substrate for liquid crystal panel having this configuration, the intersection areas of the auxiliary capacitance lines and the source lines on the substrate main body are formed to be recessed; at least a portion of the auxiliary capacitance lines is formed so as to be embedded in the recessed portions; and the auxiliary capacitance lines and the source lines are formed so as to intersect with each other over the recessed portions. Because of this, the space between the intersection areas and the color filter substrate is increased by the thickness (height) of the portion of the auxiliary capacitance lines embedded in the recessed portions. As a result, it is possible to suppress the occurrence of short circuits between the substrates due to presence of a foreign substance in the above-mentioned areas.

In another preferred aspect of the array substrate for liquid crystal panel disclosed here, the recessed portions are continuously formed under the auxiliary capacitance lines that are disposed on the substrate main body along the auxiliary capacitance lines.

In the array substrate for liquid crystal panel having this configuration, the recessed portions are formed continuously in the substrate main body under the auxiliary capacitance lines (including auxiliary capacitance electrodes) that are wired on the substrate main body. Because of this, in the areas where an auxiliary capacitance is formed, the space between the array substrate and the color filter substrate can be made larger. As a result, it is possible to suppress the occurrence of short circuits between the substrates.

Further, as another aspect, the present invention provides a liquid crystal panel that has the array substrate disclosed here.

The liquid crystal panel according to the present invention has the above-mentioned array substrate for liquid crystal panel. Because of this, it is possible to suppress an increase in the wiring line resistance and to achieve prevention of short circuits between the substrates at a higher rate. Further, the present invention provides a liquid crystal display device that has this liquid crystal panel.

### BRIEF DESCRIPTION OF THE DRAWINGS

FIG. 1 is an exploded perspective view schematically showing a configuration of a liquid crystal display device according to an embodiment of the present invention.

FIG. 2 is a cross-sectional view schematically showing a configuration of a liquid crystal display device according to an embodiment of the present invention.

FIG. 3 is a partial cross-sectional view schematically showing a configuration of a liquid crystal panel according to an embodiment of the present invention.

FIG. 4 is a partial plan view showing a pixel region in an array substrate of a liquid crystal panel according to an embodiment of the present invention.

FIG. 5 is a cross-sectional view along the line V-V in FIG. 4, schematically showing a multilayer structure of a thin film transistor (TFT).

FIG. 6A is a cross-sectional view schematically showing an array substrate according to an embodiment of the present invention in a state in which a resist film is formed at a prescribed location on a glass substrate main body that constitutes the array substrate.

FIG. 6B is a cross-sectional view schematically showing a state in which a glass substrate is patterned after photolithography is performed.

FIG. 6C is a cross-sectional view schematically showing a patterned glass substrate having a lower layer, a middle layer, and an upper layer that constitute a gate electrode laminated thereon.

FIG. 6D is a cross-sectional view schematically showing a resist film formed at a prescribed location on the upper layer of the gate electrode.

FIG. 6E is a cross-sectional view schematically showing a state in which the lower layer, the middle layer, and the upper layer of the gate electrode are patterned after photolithography is performed.

FIG. 6F is a cross-sectional view schematically showing an insulating layer and a semiconductor layer laminated on the laminated gate electrode.

FIG. 6G is a cross-sectional view schematically showing a resist film formed at a prescribed location on the semiconductor layer.

FIG. 6H is a cross-sectional view schematically showing a state in which the semiconductor layer is patterned after photolithography is performed.

FIG. 6I is a cross-sectional view schematically showing a state in which a lower layer and an upper layer of a metal film layer that constitutes a source electrode and a drain electrode are laminated on the patterned semiconductor layer.

FIG. 6J is a cross-sectional view schematically showing a resist film formed at a prescribed location on the upper layer of the metal film layer that constitutes the source electrode and the drain electrode.

FIG. 6K is a cross-sectional view showing a state in which the source electrode and the drain electrode are patterned after photolithography is performed.

FIG. 7 is a cross-sectional view along the line VII-VII in FIG. 4, schematically showing an area where a gate line and a source line intersect with each other.

FIG. 8 is a cross-sectional view along the line VIII-VIII in FIG. 4, schematically showing an area where an auxiliary capacitance line and a source line intersect with each other.

FIG. 9 is a cross-sectional view along the line IX-IX in FIG. 4, schematically showing a configuration of an auxiliary capacitance.

FIG. 10 is a cross-sectional view schematically showing a multilayer structure of a TFT in a conventional array substrate.

### DETAILED DESCRIPTION OF EMBODIMENTS

Preferred embodiments of the present invention are described below with reference to figures. Matters not specifically mentioned herein (matters other than the configuration and manufacturing method of an array substrate, for example), but necessary to implement the present invention (configuration of a light source equipped in a liquid crystal display device, electrical circuits involved in a driver system of the light source, and the like, for example) can be worked out as design matters by those skilled in the art based on conventional technologies in the field. The present invention can be implemented based on the contents disclosed in the present specification and figures and common technical knowledge in the field.

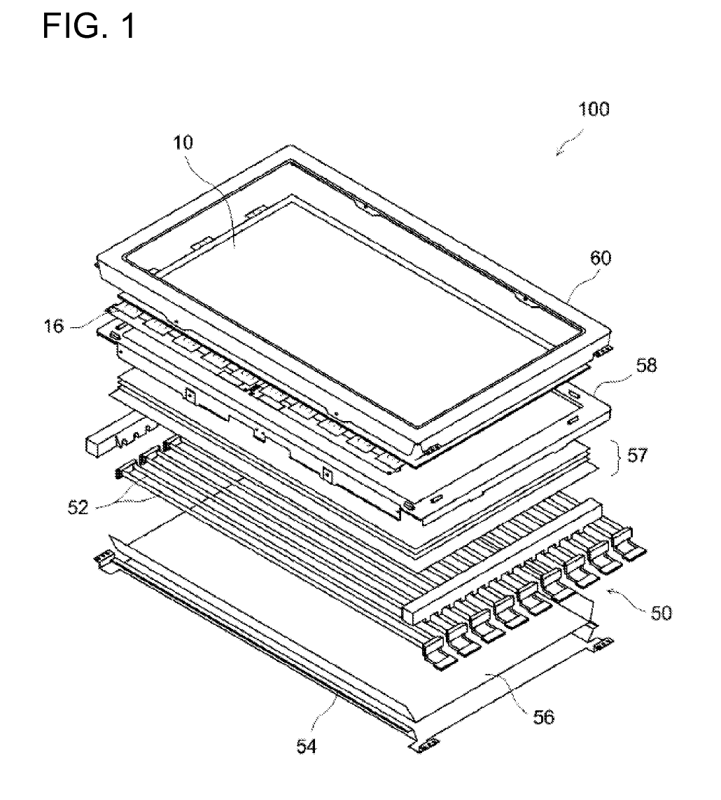

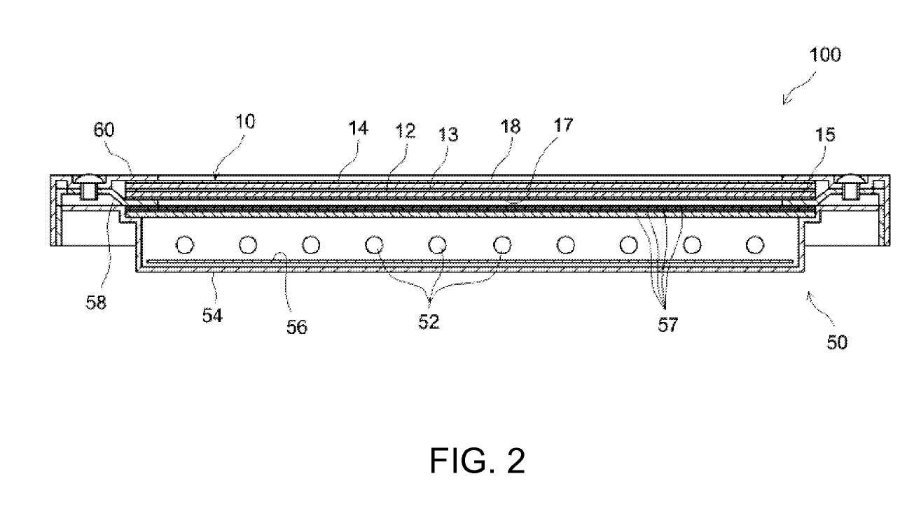

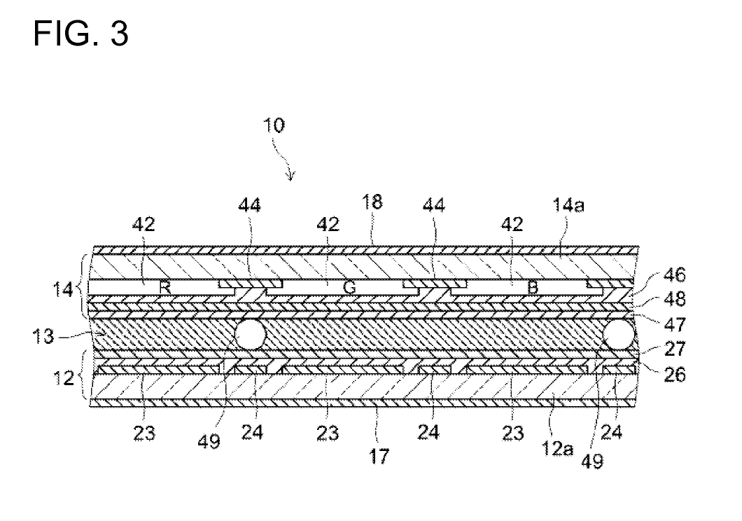

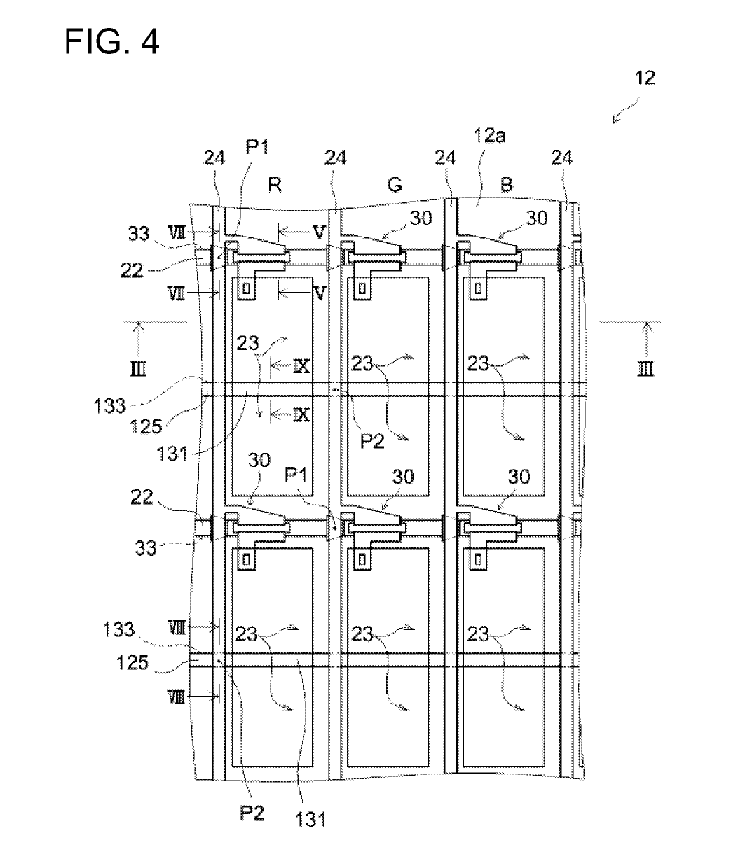

A liquid crystal panel 10 that has an array substrate 12 for liquid crystal panel according to a preferred embodiment of the present invention, and a liquid crystal display device 100 of an active matrix type (TFT type) that has the liquid crystal panel 10 are described below with reference to FIGS. 1 to 4. FIG. 1 is an exploded perspective view schematically showing a configuration of the liquid crystal display device 100 according to the present embodiment. FIG. 2 is a cross-sectional view schematically showing a configuration of the liquid crystal display device 100 of the present embodiment. FIG. 3 is a cross-sectional view schematically showing a configuration of the liquid crystal panel 10 according to the present embodiment. FIG. 4 is a plan view schematically showing the array substrate 12 for liquid crystal panel according to the present embodiment.

In the figures below, members and areas that have the same functions are given the same reference characters, and repetitive description may be abridged or avoided. Also, the dimensional relationship (length, width, thickness, and the like) in the respective figures may not necessarily reflect the actual dimensional relationship in an accurate manner. In the description below, “above” or “front side” refers to the side close to the viewer of the liquid crystal display device 100 (i.e., the liquid crystal panel side), and “under” or “back side” refers to the side away from the viewer of the liquid crystal display device 100 (i.e., the backlight device side).

With reference to FIGS. 1 and 2, a configuration of the liquid crystal display device 100 is described. As shown in FIG. 1, the liquid crystal display device 100 has the liquid crystal panel 10 and a backlight device 50, which is an external light source disposed on the back side (bottom side in FIG. 1) of the liquid crystal panel 10. The liquid crystal panel 10 and the backlight device 50 are coupled together by a frame body (bezel) 60 or the like and held integrally.

The liquid crystal panel 10 is described with reference to FIGS. 1 to 4.

As shown in FIGS. 1 to 3, the liquid crystal panel 10 generally has a rectangular shape as a whole, and in the central region, has a pixel formation region (also referred to as an effective display region or an active area) in which pixels are formed. The liquid crystal panel 10 has a sandwich structure that is constituted of a pair of transparent glass substrates 12 and 14 that face each other and a liquid crystal layer 13 sealed therebetween. The substrates 12 and 14 are cut out from a large base material called “mother glass” in the manufacturing process. Of the pair of substrates 12 and 14, one on the front side is a color filter substrate (CF substrate) 14, and the other on the back side is an array substrate 12. In peripheral portions (peripheral portion of the liquid crystal panel 10) of the array substrate 12 and the CF substrate 14, a sealing member 15 is disposed so as to seal in the liquid crystal layer 13. The liquid crystal layer 13 is made of a liquid crystal material containing liquid crystal molecules. Orientation of the liquid crystal molecules in the liquid crystal material is controlled by a voltage applied on the substrates 12 and 14, and its optical characteristics thereby change. On surfaces of the substrates 12 and 14 on the sides that do not face each other (outside), polarizing plates 17 and 18 are attached, respectively.

As shown in FIGS. 3 and 4, in the liquid crystal panel 10 disclosed herein, on the front side (side facing the liquid crystal layer 13) of a glass substrate main body 12a that constitutes the array substrate 12, pixels (more specifically, subpixels) for performing display are arranged, and a plurality of gate lines (scan wiring lines) 22 and a plurality of source lines (signal wiring lines) 24 for driving the respective pixels are formed in a grid pattern. In the substrate main body 12a, auxiliary capacitance lines (also referred to as storage capacitance lines or Cs lines) 125 that are independently wired so as to be parallel to the gate lines 22 are also disposed. In the substrate main body 12a, recessed portions 33 and 133 are formed along a wiring direction (horizontal direction in the figure) of the gate lines 22 and the auxiliary capacitance lines 125, respectively.

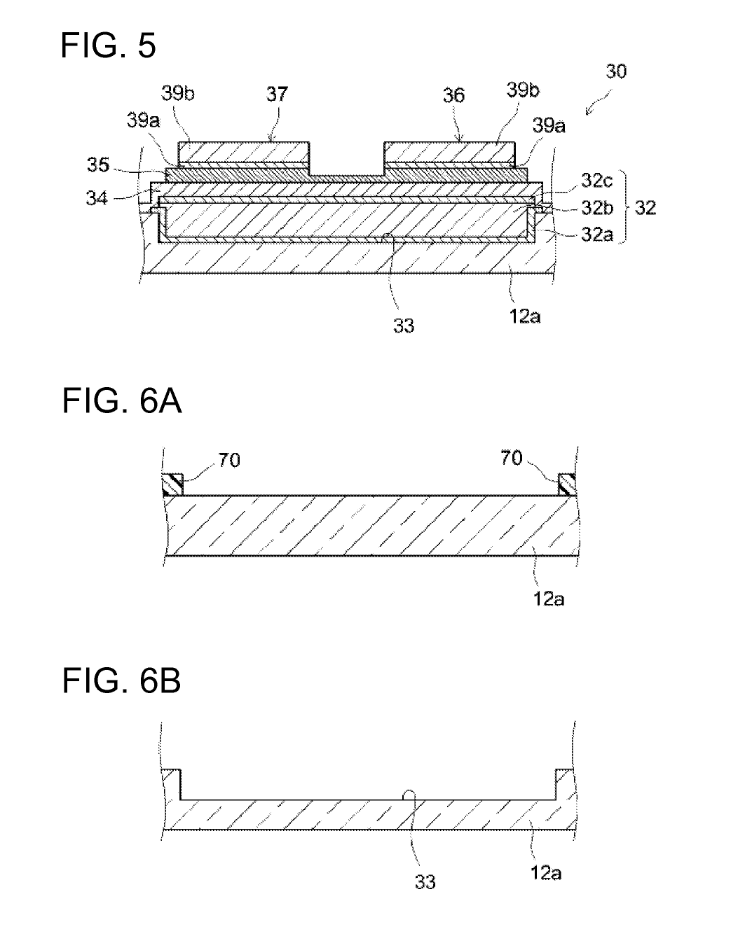

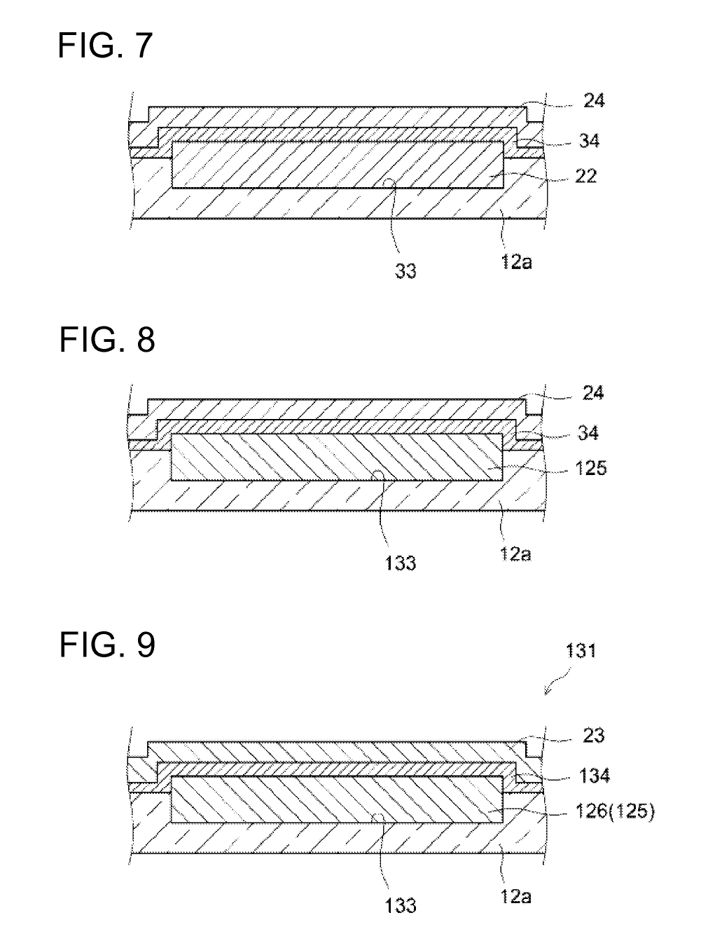

In the respective grid regions bordered by the gate lines 22 and the source lines 24, pixel electrodes 23 and thin film transistors (hereinafter may be simply referred to as “TFTs”) 30, which are switching elements, are formed. Further, auxiliary capacitances (also referred to as storage capacitances or Cs) 131 that stabilize a potential of the pixel electrodes 23 are formed. The pixel electrodes 23 are typically formed of ITO (indium tin oxide), which is a transparent conductive material, and are electrically connected to drain electrodes 37 (see FIG. 5) of the TFTs 30. A voltage corresponding to an image is applied to these pixel electrodes 23 through the gate lines 22, the source lines 24, and the thin film transistors 30 at a prescribed timing. Further, in the respective grid regions, auxiliary capacitance electrodes (also referred to as storage capacitance electrodes or Cs electrodes) 126 (see FIG. 9) are formed, and the auxiliary capacitances 131 are constituted of the auxiliary capacitance electrodes 126 and the pixel electrodes 23, respectively. The auxiliary capacitance lines 125 are electrically connected to the auxiliary capacitance electrodes 126.

As shown in FIG. 1, the gate lines 22 and the source lines 24 are connected to external driver circuits (driver ICs) 16 that are typically disposed in a periphery portion of the liquid crystal panel 10 and that can supply image signals and the like. Further, the auxiliary capacitance lines 125 are connected to an auxiliary capacitance line driver circuit, which is not shown in the figure.

As shown in FIG. 3, the pixel electrodes 23, the gate lines (see FIG. 4), and the source lines 24 are covered by a planarizing layer (also referred to as an overcoat layer) 26 that is made of an insulating material. On the planarizing layer 26, an alignment film 27 that is made of polyimide or the like is formed. An alignment treatment (rubbing treatment) has been performed to a surface of the alignment film 27 so as to determine an orientation direction of the liquid crystal molecules when no voltage is applied. The rubbing treatment is not always required. If the liquid crystal panel 10 of the present embodiment is categorized as the VA (Vertical Alignment) type, which uses a vertical alignment film, for example, the above-mentioned rubbing treatment may not be performed.

On the other hand, as shown in FIG. 3, on the back side (side facing the liquid crystal layer 13) of a glass substrate main body (glass substrate) 14a that constitutes the CF substrate 14, color filters 42 disposed at locations corresponding to the respective pixel electrodes 23 of the array substrate 12 and a black matrix (light shielding film) 44 that borders the color filters 42 of the respective colors are formed. As shown in FIG. 3, the color filters 42 have three colors, which are red (R), green (G), and blue (B). A single color filter 42 of R, G, or B faces a respective pixel electrode 23 of the array substrate 12. The black matrix 44 is formed of a metal such as Cr (chromium) so that light is not transmitted through a region between subpixels. As shown in FIG. 3, a planarizing layer 46 is formed so as to cover the color filters 42 and the black matrix 44. On a surface of the planarizing layer 46, an opposite electrode (common electrode) 48 made of ITO is formed. On a surface of the opposite electrode 48, an alignment film 47 is formed. An alignment treatment (as in the case of the alignment film 27, the alignment film treatment may not be performed) has been performed to a surface of the alignment film 47. Here, the alignment direction of the alignment film 27 of the array substrate 12 and the alignment direction of the alignment film 47 of the CF substrate are different from each other by 90°.

As shown in FIG. 3, a plurality of spacers 49 in a circular shape or a columnar shape (circular shape in FIG. 3) are dispersed and sandwiched in a space (gap) between the array substrate 12 and the CF substrate 14. The spacers 49 are formed of a resin material that can be elastically deformed, for example. This way, the space between the substrates 12 and 14 is maintained by the sealing member 15 (see FIG. 2) described above and the spacers 49, and the thickness of the liquid crystal layer 13 is kept constant.

Furthermore, as shown in FIGS. 2 and 3, the polarizing plates 17 and 18 are respectively attached to the surfaces of the substrates 12 and 14 on the sides not facing each other.

As shown in FIGS. 1 and 2, a bezel 60 is attached on the front side of the liquid crystal panel 10. Further, a frame 58 is attached on the back side of the liquid crystal panel 10. The bezel 60 and the frame 58 hold the liquid crystal panel 10 therebetween. The frame 58 has an opening in a portion corresponding to the effective display region, which is the central region of the liquid crystal panel 10. On the back side of the liquid crystal panel 10 (back side of the bezel 60), a backlight device 50 housed in a case 54 is attached.

As shown in FIG. 1, the backlight device 50 is constituted of a plurality of linear light sources (fluorescent tubes, for example; typically cold cathode tubes) 52 and the case (chassis) 54 that houses the light sources 52. The case 54 has a box shape that has an opening facing the front side. Inside the case 54, the light sources 52 are arranged in parallel with each other. Between the case 54 and the light sources 52, a reflective member 56 is disposed for efficiently reflecting light from the light sources 52 towards the viewer.

In the opening of the case 54, a plurality of sheet-shaped optical members 57 are laminated so as to cover the opening. The optical members 57 include a diffusion plate, a diffusion sheet, a lens sheet, and a brightness enhancement sheet disposed in this order from the side closer to the backlight device 0, for example. However, the configuration thereof is not limited to this combination and order. Further, the frame 58 that is substantially in a frame shape is disposed in the case 54 so as to hold the optical members 57 in place in the case 54.

On the back side of the case 54, an inverter circuit board (not shown) for mounting an inverter circuit and an inverter transformer (not shown) as a booster circuit that supplies power to the respective light sources 52 are disposed. However, they do not characterize the present invention, and therefore, descriptions thereof are omitted.

The liquid crystal display device 100 having the configuration described above operates the liquid crystal molecules in the liquid crystal layer 13 by applying the controlled voltages on the array substrate 12 and the CF substrate 14, thereby transmitting or blocking light from the backlight device 50 in the liquid crystal panel 10. The liquid crystal display device 100 also displays a desired image in the effective display region of the liquid crystal panel 10, while controlling the luminance and the like of the backlight device 50.

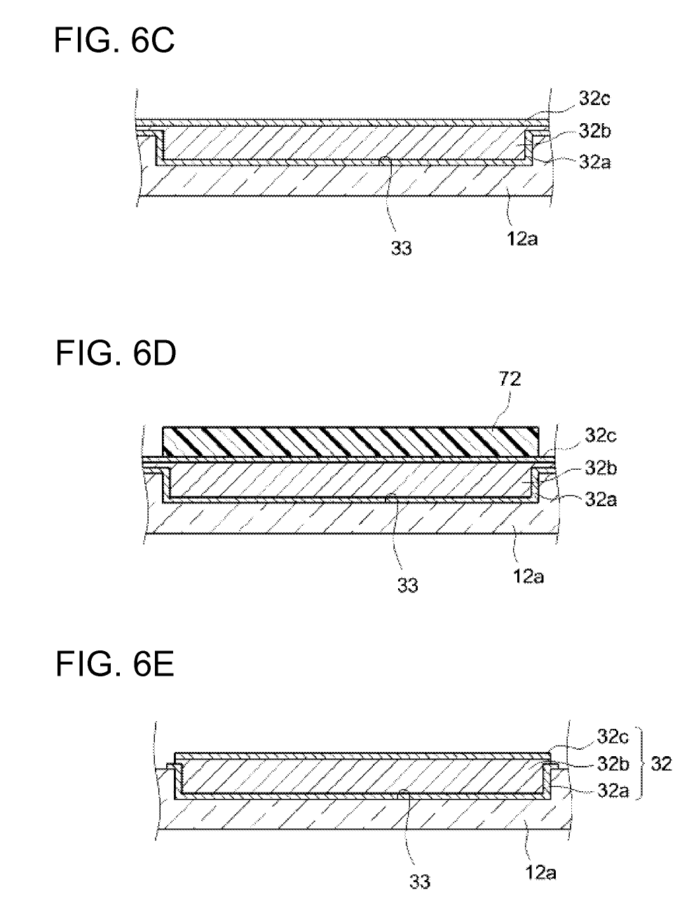

Next, the TFT 30 in the array substrate 12 according to the present embodiment is described in further detail with reference to FIGS. 5 to 6K. FIG. 5 is a cross-sectional view along the line V-V in FIG. 4, and schematically shows a multilayer structure of the TFT. FIGS. 6A to 6K are cross-sectional views schematically showing steps of forming the multilayer structure of the TFT 30 in order. FIG. 6A is a cross-sectional view schematically showing a resist film 70 formed at a prescribed location on a glass substrate 12a that constitutes the array substrate 12. FIG. 6B is a cross-sectional view schematically showing a state in which the glass substrate 12a is patterned after photolithography is performed. FIG. 6C is a cross-sectional view schematically showing a lower layer 32a, a middle layer 32b, and an upper layer 32c that constitute a gate electrode 32 laminated on the patterned glass substrate 12a. FIG. 6D is a cross-sectional view schematically showing a resist film 72 formed at a prescribed location on the upper layer 32c of the gate electrode 32. FIG. 6E is a cross-sectional view schematically showing a state in which the lower layer 32a, the middle layer 32b, and the upper layer 32c of the gate electrode 32 are patterned after photolithography is performed. FIG. 6F is a cross-sectional view schematically showing an insulating layer 34 and a semiconductor layer 35 that are laminated on the laminated gate electrode 32. FIG. 6G is a cross-sectional view schematically showing a resist film 74 formed at a prescribed location on the semiconductor layer 35. FIG. 6H is a cross-sectional view schematically showing a state in which the semiconductor layer 35 is patterned after photolithography is performed. FIG. 6I is a cross-sectional view schematically showing a state in which a lower layer 39a and an upper layer 39b of a metal film layer, which becomes a source electrode 36 and a drain electrode 37, are laminated on the patterned semiconductor layer 35. FIG. 6J is a cross-sectional view schematically showing a resist film 76 formed at a prescribed location on the upper layer 39a of the metal film layer that becomes the source electrode 36 and the drain electrode 37. FIG. 6K is a cross-sectional view showing a state in which the source electrode 36 and the drain electrode 37 are patterned after photolithography is performed. FIG. 5 and FIGS. 6A to 6K are schematic cross-sectional views, and therefore, they do not exactly match the schematic plan view of FIG. 4.

As shown in FIG. 4, the array substrate 12 of the liquid crystal panel 10 of the present embodiment has the glass substrate (substrate main body) 12a made of glass, the plurality of gate lines 22, the plurality of source lines 24 that intersect with the gate lines 22 at a right angle, and the plurality of TFTs 30 that are electrically connected to the respective gate lines 22 and source lines 24. In the array substrate 12 of the present embodiment, the TFTs 30 are disposed over the gate lines 22 (more specifically, over the gate lines 22 near the intersection areas P1 (see FIG. 4) of the gate lines 22 and the source lines 24) for higher pixel aperture ratio.

As shown in FIG. 5, in the array substrate 12, the TFT 30 has a reverse staggered, multilayer structure that includes the gate electrode 32 formed on the glass substrate 12a, the insulating (film) layer 34 formed (laminated) on the gate electrode 32, the semiconductor layer 35 formed on the insulating layer 34, and the source electrode 36 and the drain electrode 37 formed on the semiconductor layer 35. The gate electrode 32 is electrically connected to the gate line 22 (see FIG. 4); the source electrode 36 is electrically connected to the source line 24 (see FIG. 4); and the drain electrode 37 is electrically connected to the pixel electrode 23 (see FIG. 4), respectively.

As shown in FIG. 5, in a TFT 30 formation portion of the glass substrate 12a of the present embodiment, a recessed portion 33 that is recessed in a prescribed depth from the peripheral area (region) thereof is formed. Further, on the recessed portion 33, the gate electrode 32 having a three-layer structure in which an aluminum (Al) layer is sandwiched by two titanium (Ti) layers is formed, and at least a portion of the gate electrode 32 is embedded in the recessed portion 33. In other words, the three-layer structure is constituted of the lower layer 32a that is made of Ti and that is laminated on the recessed portion 33 formed in the substrate main body 12a, the middle layer 32b that is made of AL and that is laminated on the lower layer 32a, and the upper layer 32c that is made of Ti and that is laminated on the middle layer 32b. Further, on the upper layer 32c, the insulating layer 34 and the semiconductor layer 35 are formed in this order. Above the semiconductor layer 35, the source electrode 36 and the drain electrode 37 are formed. In the present embodiment, a portion of the gate electrode 32 (the lower layer 32a and the middle layer 32b) is embedded in the recessed portion 33 of the glass substrate 12a, but the entire gate electrode 32 may also be embedded.

The insulating layer 34 formed on the upper layer 32c of the gate electrode 32 having the three-layer structure serves as a gate insulating film, and, in a manner similar to a gate insulating film in a conventional TFT, is made of a nitride (SiNx) and/or an oxide (SiOx) of silicon (Si) or the like. The insulating layer 34 may have a multilayer structure (two-layer structure, for example).

The semiconductor layer 35 is made of an amorphous silicon (α-Si) layer that serves as a switch of the TFT 30 and an n⁺ amorphous silicon (n⁺ α-Si) layer that is laminated on the α-Si layer. The n⁺ α-Si layer is disposed so as to obtain an excellent ohmic contact between the α-Si layer, and the source electrode 36 and the drain electrode 37, and is formed of α-Si doped with phosphorus (P) as an impurity. Here, an insulating layer that is made of SiNx and that serves as a channel protective film (i-stopper film) may be interposed between the α-Si layer and the n⁺ α-Si layer.

Above the semiconductor layer 35, the source electrode 36 and the drain electrode 37 are formed. The electrodes 36 and 37 are both made of a metal film layer having a two-layer structure, and the metal film layer is constituted of a lower layer 39a formed of Ti and an upper layer 39b formed of Al.

By having the configuration described above, the TFT 30 of the present embodiment has a multilayer structure in which at least a portion of the gate electrode 32 is embedded in the recessed portion 33 of the glass substrate 12a.

Next, with reference to FIGS. 6A to 6K, an example of a manufacturing method of the array substrate 12 and the liquid crystal panel 10 having the array substrate 12 is described, focusing on the TFT 30 region. In the manufacturing process of the array substrate 12 of the present embodiment, the order and the type (film material) of thin films laminated by photolithography may be similar to those of conventional array substrates, and there is no special limitation. General manufacturing process is described below, but the present invention is not limited thereto.

First, the glass substrate 12a cut out from a mother glass is prepared. Then, a resist film 70 made of ultraviolet photosensitive resin is applied on the glass substrate 12a (resist application step). The resist film (positive resist film 70, for example) is cured by pre-baking (pre-drying) (pre-baking step). Next, a patterned mask is placed on the cured resist film, and over the mask, the ultraviolet ray having a prescribed wavelength (the i-ray having a wavelength of 365 nm, for example) is radiated for exposure (exposure step). After the exposure, the glass substrate 12a is immersed in a developing solution, and then rinsed with purified water to dissolve and remove the exposed portion of the positive resist film 70 (development step). Next, post-baking is performed (post-baking step). This way, as shown in FIG. 6A, the resist film 70 (unexposed portion of the positive resist film) on which the mask pattern is transferred is formed on the glass substrate 12a.

Next, etching is conducted to form the recessed portion 33 having a prescribed depth in a prescribed portion of the glass substrate 12a where the resist film 70 is not formed (etching step). For the etching step, dry etching and wet etching can be employed. Dry etching utilizing the plasma-generated gas phase radicals or the like can preferably be used, for example. Here, the depth of the recessed portion 33 is set by appropriately adjusting etching process conditions (etching rate, for example). As the depth of the recessed portion 33, 200 nm to 300 nm is appropriate (250 nm in the present embodiment). Lastly, the resist film 70 is removed from the glass substrate 12a by oxygen gas plasma or the like, for example (resist removal step).

This way, the recessed portion 33 is formed in the top surface of the glass substrate 12a as shown in FIG. 6B.

Next, the glass substrate 12a in which the recessed portion 33 is formed is washed (wash step). Thereafter, as shown in FIG. 6C, the lower layer 32a made of Ti, the middle layer 32b made of Al, and the upper layer 32c made of Ti, which constitute the gate electrode 32, are deposited (vapor deposited) by sputtering on the glass substrate 12a (film formation step). As the film thickness of the lower layer 32a, 30 nm to 40 nm is appropriate (35 nm in the present embodiment). As the film thickness of a portion of the middle layer 32b that is formed in the recessed portion 33 in the glass substrate 12a, 310 nm to 410 nm is appropriate (360 nm in the present embodiment). As the film thickness of a portion of the middle layer 32b excluding the portion formed in the recessed portion 33 in the glass substrate 12a, 110 nm to 210 nm is appropriate (210 nm in the present embodiment). As the film thickness of the upper layer 32c, 60 nm to 160 nm is appropriate (110 nm in the present embodiment).

Further, as shown in FIGS. 6D and 6E, in a resist application step, a resist 72 is applied on the three layers laminated in the film formation step, and the three layers are patterned by a series of steps including pre-baking, exposure, development, post-baking, etching, and resist removal. The gate electrode 32 is formed such that a portion of the three layers is embedded in the recessed portion 33 formed in the glass substrate 12a.

Next, as shown in FIG. 6F, in a film formation step, the insulating layer (gate insulating film) 34 and the semiconductor layer 35 are formed in this order on the gate electrode 32. Here, four layers including the insulating layer 34 formed of SiNx or the like, the semiconductor layer 35 having a two-layer structure of an α-Si layer and an n⁺ α-Si layer, and the channel protective film layer that may be interposed between the two layers of the semiconductor layer 35 can be laminated continuously by plasma CVD. As the film thickness of the insulating layer 34, 330 nm to 500 nm is appropriate (410 nm in the present embodiment). As the film thickness of the α-Si layer of the semiconductor layer 35, 190 nm to 280 nm is appropriate (230 nm in the present embodiment). As the film thickness of the n⁺ α-Si layer, 44 nm to 66 nm is appropriate (55 nm in the present embodiment). As the film thickness of the channel protective film, 210 nm to 320 nm is appropriate (260 nm in the present embodiment).

Further, as shown in FIGS. 6G and 6H, in a resist application step, a resist 74 is applied on the semiconductor layer 35, which was laminated in the film formation step, and through a series of steps including pre-baking, exposure, development, post-baking, etching, and resist removal, the patterned semiconductor layer 35 is formed.

Next, as shown in FIG. 6I, in a manner similar to above, the lower layer 39a, which is a layer of the two-layered metal film layer that becomes the source electrode 36 and the drain electrode 37, is formed of Ti on the semiconductor layer 35, and the upper layer 39b made of Al is formed thereon. Here, the lower layer 39a was formed by sputtering in a film thickness of 30 nm to 40 nm (35 nm in the present embodiment). The upper layer 39b was formed by sputtering in a film thickness of 230 to 310 nm (270 nm in the present embodiment).

Further, as shown in FIGS. 6J and 6K, a resist film 76 is formed on the upper layer 39b, and thereafter, by performing steps including exposure, development, etching, resist removal, and the like, the source electrode 36 and the drain electrode 37 that have a two-layer structure can be formed. Here, in the etching step, the area (channel) between the source electrode 36 and the drain electrode 37 is preferably etched until the semiconductor layer 35 (to be exact, an outer layer of the channel protective film formed between the α-Si layer and the n⁺ α-Si layer) is exposed.

Next, an insulating film (not shown) made of SiNx is formed by plasma CVD over the source electrode 36 and the drain electrode 37, which were formed as described above, and the semiconductor layer 35 exposed in the channel between the electrodes 36 and 37, thereby forming the TFT 30. Further, a transparent conductive film made of ITO is formed on the insulating film by sputtering, and is patterned such that it serves as the pixel electrodes 23 (see FIG. 3), thereby forming a pixel region. Next, the planarizing layer 26 (see FIG. 3) is formed by a prescribed method (photolithography, for example).

Next, by an inkjet method, for example, a constituting material for an alignment film (polyimide material, for example) is applied on the planarizing layer 26. Then, a rubbing treatment (a treatment in which the surface of the film is rubbed with a rubbing cloth along a prescribed direction, for example) for controlling the orientation of the liquid crystal molecules is performed, thereby forming the alignment film 27.

The array substrate 12 is manufactured in the manner described above.

Next, the CF substrate 14 is manufactured. The CF substrate 14 can be manufactured in a manner similar to the conventional method. As a preferred method, in a manner similar to the array substrate 12, photolithography can be used. In this method, first, on the glass substrate 14a, the black matrix 44, which becomes a frame bordering the color filters 42 of the respective colors, is formed in a grid pattern typically by photolithography. Then, an R (red) pigment-dispersed resist (a resist material obtained by dispersing red pigments in a transparent resin), for example, is applied uniformly over the glass substrate with the black matrix 44 formed thereon. Thereafter, exposure is performed with an aligned mask, and the pattern of the R color filter is printed. Next, development is performed to form R subpixels (color filters) in a prescribed pattern. G (green) and B (blue) color filters are formed in the same manner. Then, the planarizing layer 46 and a transparent ITO conductive film that becomes the opposite electrode 48 are formed on the color filters 42 and the black matrix 44 by sputtering, photolithography, or the like, for example. The method of forming the alignment film 47 on the opposite electrode 48 may be the same as the method of forming the alignment film 27 on the array substrate 12.

The CF substrate 14 is manufactured in the manner described above.

Using the array substrate 12 and the CF substrate 14 obtained as described above, the liquid crystal panel 10 is manufactured as follows. The array substrate 12 and the CF substrate 14 are bonded to each other (see FIGS. 2 and 3). That is, first, a sealing material (sealing adhesive agent made of thermosetting resin or ultraviolet curable resin, for example) is applied on the peripheral portion of the array substrate 12 to form the sealing member 15. Next, in order to provide a space (gap) between the array substrate 12 and the CF substrate 14, the spacers 49 are dispersed over the array substrate 12. Thereafter, the CF substrate 14 is placed on the array substrate 12 such that the respective sides having the alignment films 27 and 47 face each other, and the substrates are bonded to each other.

Next, the pair of substrates 12 and 14 bonded to each other is maintained in a vacuum environment, and a liquid crystal material is injected into the gap between the substrates by capillarity action (dipping method). Once the gap is filled with the liquid crystal material, the injection inlet is sealed (the inlet is blocked using an ultraviolet curable adhesive agent, for example). Lastly, the polarizing plates 17 and 18 are attached to respective sides of the substrates 12 and 14 that are facing away from each other (i.e., sides not having the alignment films 27 and 47 formed thereon). The liquid crystal panel 10 is completed in this manner.

On the front side and the back side of the completed liquid crystal panel 10, the bezel 60 and the frame 58 are disposed, respectively, to support the liquid crystal panel 10. On the back side of the frame 58, the optical members 57 and the backlight device 50 housed in the case 54 are attached. The liquid crystal display device 100 is formed in this manner.

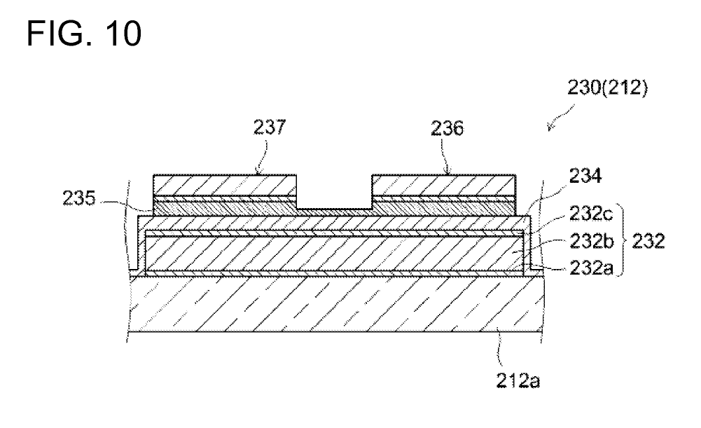

Here, a difference between the array substrate 12 manufactured as described above and a conventional array substrate 212 is described with reference to FIG. 10, using a structure of a TFT 230 as an example. FIG. 10 is a cross-sectional view schematically showing a multilayer structure of the TFT 230 of the conventional array substrate 212.

As shown in FIG. 10, in the multilayer structure of the TFT 230 of the conventional array substrate 212, a lower layer 232a, a middle layer 232b, and an upper layer 232c that constitute the gate electrode 232 are formed on a glass substrate 212a. Further, an insulating layer (gate insulating film) 234, and then a semiconductor layer 235 are layered. On the semiconductor layer 235, a source electrode 236 and a drain electrode 237 are formed, respectively. In an area (channel) between the electrodes 236 and 237, an α-Si layer of the semiconductor layer 235 that is covered by a channel protective film is present. Here, the TFT 230 formation portion of the conventional array substrate 212 has a multilayer structure in which the gate electrode 232 is formed on the planarized glass substrate 212a and the source electrode 236 and the drain electrode 237 are formed above the gate electrode, and therefore, the TFT 230 formation portion protrudes from the top surface portion of the area surrounding the TFT 230. When the array substrate 212 having this configuration is used as a liquid crystal panel, the distance (space) between the array substrate and a CF substrate that is disposed so as to face the array substrate becomes shorter (smaller) in the areas where the source electrode 236 and the drain electrode 237 are disposed. Therefore, if an impurity (foreign substance) is trapped in the liquid crystal layer disposed between the substrates, and is present in an area where the space between the substrates is small, undesirable short circuits can occur between the substrates at a higher rate as compared with the area where the space between the substrates is larger.

On the other hand, as shown in FIGS. 5 and 6K, in the array substrate 12 of the present embodiment, the recessed portion 33 is formed in the glass substrate 12a, and the gate electrode 32 (in the present embodiment, the lower layer 32a and the middle layer 32b) is formed so as to be embedded in the recessed portion 33. Because of this, the thickness of the TFT 30 formation portion is reduced (made thinner) by the thickness of the portion of the gate electrode 32 that is embedded in the glass substrate 12a. Therefore, in the liquid crystal panel 10 (see FIG. 3), which is configured to have the array substrate 12 and the CF substrate 14 facing each other, the space between the substrates 12 and 14 in the areas where the source electrode 36 and the drain electrode 37 are located (i.e., the TFT 30 formation portion) becomes larger as compared with the conventional array substrate 212. As a result, a liquid crystal panel that is capable of suppressing the occurrence of short circuits between the array substrate 12 and the CF substrate 14 can be achieved by the liquid crystal panel 10 of the present embodiment.

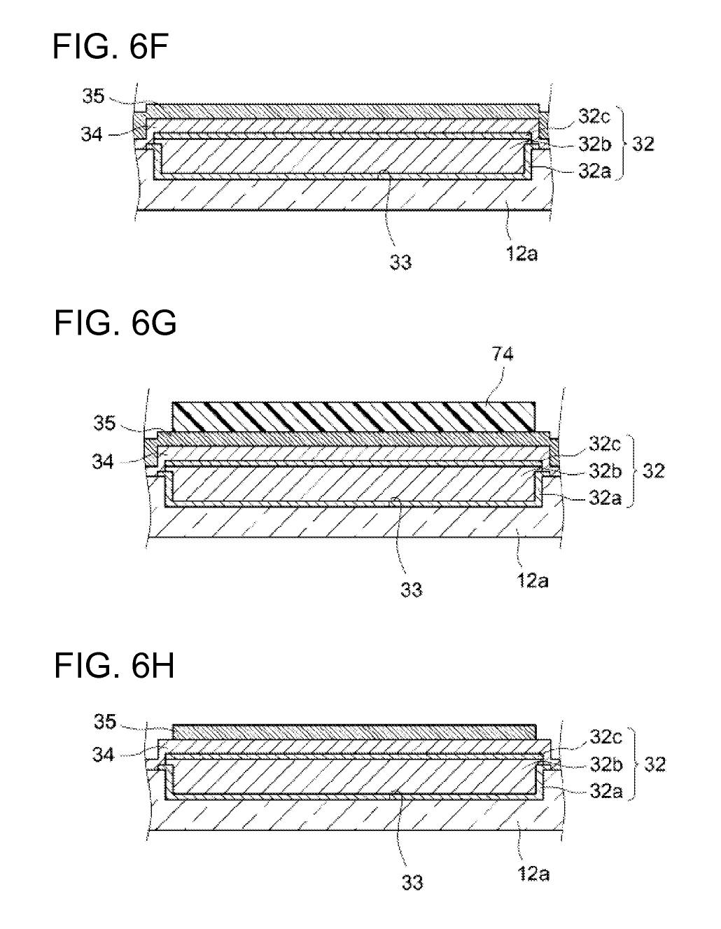

Next, a structure of an intersection area of the gate line 22 and the source line 24 in the array substrate 12 is described. FIG. 7 is a cross-sectional view along the line VII-VII in FIG. 4, schematically showing an area where the gate line 22 and the source line 24 intersect with each other. As shown in FIG. 4, the array substrate 12 of the present embodiment has, in the pixel region thereof, a plurality of areas P1 where the gate lines 22 that supply ON/OFF signals for the TFTs 30 and the source lines 24 that supply display signals (signal voltages) to the TFTs 30 intersect with each other.

As shown in FIG. 7, in the glass substrate 12a, at least in the intersection area P1 of the gate line 22 and the source line 24, the recessed portion 33 that is recessed from non-intersection areas that surround the intersection area P1 is formed. Further, at least a portion of the gate line 22 is disposed inside the recessed portion 33, and the gate lines 22 intersects with the source line 24 over the recessed portion 33. As described, the glass substrate 12a is recessed in the intersection area P1, and therefore, when the gate line 22 is disposed on the recessed portion 33, and the source line 24 is disposed on the gate line 22 so as to intersect therewith, the thickness of the intersection area P1 becomes smaller than that of the conventional array substrate (array substrate in which a recessed portion is not formed). Consequently, in the intersection area P1, the space between the array substrate 12 and the CF substrate 14 becomes larger as compared with the conventional array substrate. Here, in the array substrate 12 of the present embodiment, the recessed portion 33 is continuously formed under the gate line 22 along the gate line 22, however, the recessed portion 33 is not limited thereto as long as it is formed at least in an area where the gate line 22 and the source line 24 intersect with each other.

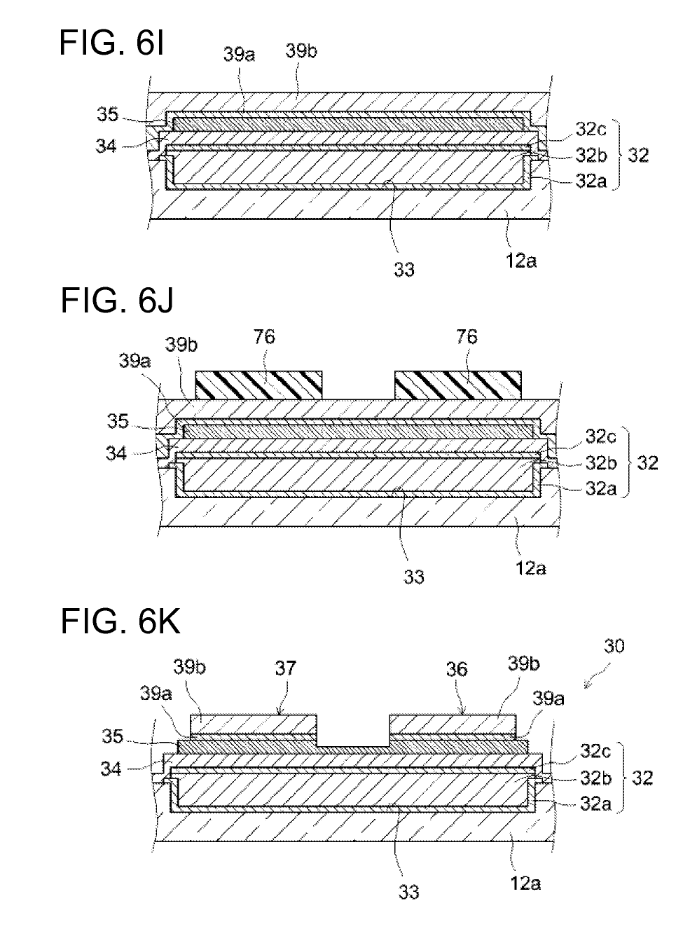

Next, a structure of an area where the auxiliary capacitance line 125 and the source line 24 intersect with each other in the array substrate 12 is described. FIG. 8 is a cross-sectional view along the line VIII-VIII in FIG. 4, schematically showing an area where the auxiliary capacitance line 125 and the source line 24 intersect with each other. As shown in FIG. 4, the array substrate 12 of the present embodiment has, in the pixel region thereof, a plurality of areas P2 where the auxiliary capacitance lines 125, which supply a prescribed voltage to the auxiliary capacitances 131, intersect with the source lines 24.

As shown in FIG. 8, in the glass substrate 12a, a recessed portion 133 that is recessed from non-intersection areas that surround the intersection area P2 is formed at least in the intersection area P2 of the auxiliary capacitance line 125 and the source line 24. Further, the auxiliary capacitance line 125 is disposed inside the recessed portion 133, and intersects with the source line 24 over the recessed portion 133. According to this configuration, the thickness of the intersection area P2 becomes thinner than that of the conventional array substrate (array substrate in which a recessed portion is not formed), and in the intersection area P2, the space between the array substrate 12 and the CF substrate 14 becomes larger as compared with the conventional array substrate.

Next, the auxiliary capacitance 131 in the array substrate 12 is described. FIG. 9 is a cross-sectional view along the line IX-IX in FIG. 4, schematically showing a structure of the auxiliary capacitance 131.

As shown in FIG. 9, in the formation area of the auxiliary capacitance 131 in the glass substrate 12a of the present embodiment, the recessed portion 133 that is recessed from the surrounding area (region) thereof in a prescribed depth is formed. On the recessed portion 133, the auxiliary capacitance electrode 126 (auxiliary capacitance line 125) having a three-layer structure similar to that of the gate electrode 32 is formed, and at least a portion thereof is embedded in the recessed portion 133. Further, on the auxiliary capacitance electrode 126, an insulating layer 134, which is made of the same material as that of the insulating layer 34 of the TFT, and the pixel electrode 23 are formed in this order. The pixel electrode 23 is electrically connected to the drain electrode 37 of the TFT 30. By having the configuration described above, the auxiliary capacitance 131 of the present embodiment has the multilayer structure in which at least a portion of the auxiliary capacitance electrode 126 is embedded in the recessed portion 133 of the glass substrate 12a.

According to this configuration, the thickness of the formation area of the auxiliary capacitance 131 is reduced, and thus the space between the auxiliary capacitance 131 and the CF substrate 14 becomes larger. As a result, a liquid crystal panel that is capable of suppressing the occurrence of short circuits between the auxiliary capacitance 131 and the CF substrate 14 can be achieved.

Preferred embodiments of the present invention were described above with reference to figures. However, the array substrate for liquid crystal panel of the present invention is not limited thereto. In the embodiments above, recessed potions are provided in the glass substrate for the TFT formation portion, the auxiliary capacitance formation portion, the intersection areas of the gate lines and the source lines, and the intersection areas of the auxiliary capacitance lines and the source lines, respectively, for example. However, the recessed portion may be formed in one of these areas.

Further, there is no special limitation on the shape of the recessed portion (recessed shape) as long as the objects of the present invention described above are achieved. The cross-sectional shape of the recessed portion is not limited to the rectangular shape as described above, for example, and may be in a trapezoidal shape, a semicircular shape, or the like.

Further, the substrate is not limited to a glass substrate, and may be a substrate made of another material (synthetic resin or the like).

### INDUSTRIAL APPLICABILITY

By using an array substrate for liquid crystal panel provided by the present invention, it is possible to constitute a liquid crystal panel that is thin and that is capable of suppressing the occurrence of short circuits between substrates, and therefore, a highly reliable liquid crystal display device equipped with this panel can be provided.

10 liquid crystal panel

12 array substrate

12a glass substrate (substrate main body)

13 liquid crystal layer

14 color filter (CF) substrate

14a glass substrate

15 sealing member

16 external driver circuit

17, 18 polarizing plates

22 gate line

23 pixel electrode

24 source line

26 planarizing layer

27 alignment film

30 thin film transistor (TFT)

32 gate electrode

32a lower layer

32b middle layer

32c upper layer

33 recessed portion

34 insulating layer

35 semiconductor layer

36 source electrode

37 drain electrode

39a lower layer

39b upper layer

42 color filter

44 black matrix

46 planarizing layer

47 alignment film

48 opposite electrode

49 spacer

50 backlight device

52 light source

54 case

56 reflective member

57 optical member

58 frame

60 bezel

70, 72, 74, 76 resist films

100 liquid crystal display device

125 auxiliary capacitance line

126 auxiliary capacitance electrode

131 auxiliary capacitance

133 recessed portion

134 insulating layer

212 array substrate

212a glass substrate

230 TFT

232 gate electrode

232a lower layer

232b middle layer

232c upper layer

234 insulating layer

235 semiconductor layer

236 source electrode

237 drain electrode

1. An array substrate for liquid crystal panel, comprising a substrate main body, a plurality of gate lines, a plurality of source lines that intersect with said gate lines, and a plurality of thin film transistors electrically connected to respective gate lines and respective source lines,
wherein each of said thin film transistors is formed to have a multilayer structure that has at least a gate electrode, a source electrode, and a drain electrode,
wherein in at least a part of a formation portion of each of said thin film transistors, said substrate main body has a recessed portion that is recessed from a surrounding portion of the formation portion of said thin film transistor, and
wherein one of said gate electrode, said source electrode, and said drain electrode is formed such that at least a portion thereof is embedded in said recessed portion.

2. The array substrate for liquid crystal panel according to claim 1, wherein each of said thin film transistor has a multilayer structure having the gate electrode formed on said substrate main body, an insulating film that is formed closer to a top of a substrate than said gate electrode, a semiconductor film that is formed closer to the top of the substrate than said insulating film, and the source electrode and the drain electrode that are formed closer to the top of the substrate than said semiconductor film, and
wherein at least a portion of said gate electrode is formed so as to be embedded in said recessed portion.

3. The array substrate for liquid crystal panel according to claim 1, wherein, in said substrate main body, at least intersection areas of said gate lines and said source lines that are disposed on said substrate main body are formed in recessed portions that are recessed from non-intersection areas adjacent to said intersection areas, and
wherein at least a portion of said gate lines is formed so as to be embedded in said recessed portions, and said gate lines and said source lines are arranged so as to intersect with each other over said recessed portions.

4. The array substrate for liquid crystal panel according to claim 3, wherein said recessed portions are formed continuously under said gate lines disposed on said substrate main body along said gate lines.

5. The array substrate for liquid crystal panel according to claim 1, wherein said array substrate further comprises a plurality of auxiliary capacitance lines that intersect with said source lines,
wherein, in said substrate main body, at least intersection areas of said auxiliary capacitance lines and said source lines that are disposed on said substrate main body are formed in recessed portions that are recessed from non-intersection areas adjacent to said intersection areas, and
wherein at least a portion of said auxiliary capacitance lines is formed so as to be embedded in said recessed portions, and said auxiliary capacitance lines and said source lines are arranged so as to intersect with each other over said recessed portions.

6. The array substrate for liquid crystal panel according to claim 5, wherein said recessed portions are continuously formed under said auxiliary capacitance lines that are disposed on said substrate main body along said auxiliary capacitance lines.

7. A liquid crystal panel, comprising the array substrate for liquid crystal panel according to claim 1.

8. A liquid crystal display device, comprising the liquid crystal panel according to claim 7.
